(19) United States
(12) Patent Application Publication
(10) Pub. No.: US 2009/0246385 A1
(43) Pub. Date: Oct. 1, 2009

(54) Control of crystal orientation and stress in sputter deposited thin films

(75) Inventors: Valery FELMETSGER, Goleta, CA (US); Pavel N. LAPTEV, Ventura, CA (US)

Correspondence Address: TUE NGUYEN, 496 OLIVE AVE, FREMONT, CA, 94539, US

(73) Assignee: TEGAL CORPORATION, Petaluma, CA (US)

(21) Appl. No.: 12/411,369

(22) Filed: Mar. 25, 2009

Related U.S. Application Data
(60) Provisional application No. 61/039,354, filed on Mar. 25, 2008.

(51) Int. Cl. B05D 3/14; C23C 14/34; B05D 5/00

(52) U.S. Cl. 427/301; 204/192.17; 204/192.18; 427/402

(57) ABSTRACT

A two step thin film deposition process is disclosed to provide for the simultaneous achievement of controlled stress and the achievement of preferred crystalline orientation in sputter-deposited thin films. In a preferred embodiment, a first relatively short deposition step is performed without substrate bias to establish the crystalline orientation of the deposited film followed by a second, typically relatively longer deposition step with an applied rf bias to provide for low or no stress conditions in the growing film. Sputter deposition without substrate bias has been found to provide good crystal orientation and can be influenced through the crystalline orientation of the underlying layers and through the introduction of intentionally oriented seed layers to promote preferred crystalline orientation. Conversely, sputter deposition with substrate bias has been found to provide a means for producing stress control in growing films.

This application claims priority from U.S. provisional patent application Ser. No. 61/039,354, filed on Mar. 25, 2008, entitled “Stress control in reactive sputtering”, which is incorporated herein by reference.

### FIELD OF THE INVENTION

The present invention relates to a method for the deposition of thin films that simultaneously exhibit preferred crystalline orientation and preferred stress characteristics in sputter deposition equipment.

### BACKGROUND OF THE INVENTION

In recent years, remarkable progress has been achieved in developing new techniques for sputter deposition of oxide, nitride, and oxy-nitride thin films such as aluminum nitride, aluminum oxide, silicon nitride, silicon oxide, tantalum oxide, and tantalum oxynitride, among others. These films are being utilized in increasingly demanding ways that require increasing levels of control of the film properties. For example, piezoelectric aluminum nitride films used in various electroacoustic applications such as surface acoustic wave (SAW) and bulk acoustic wave (BAW) devices, thin film bulk acoustic resonators (FBAR) and microelectromechanical systems (MEMS) require dielectric films that are highly uniform, with low or no stress, and with a specific crystallographic orientation. Piezoelectric aluminum nitride films with highly oriented (002) crystal orientation are widely used in these devices. The performance of such devices is substantially dependent on the properties of the thin films that are used to fabricate these structures, which in turn, are substantially dependent on the sputter deposition equipment and the associated processes used to deposit the thin films that are employed in this equipment. In particular, the properties of crystalline orientation and the types and levels of stress in the growing film depend on, among other parameters, the configuration of the sputtering equipment, the pressure and power levels used during the deposition, the distribution of the power levels and frequency, or frequencies, used during the sputtering process, and the specific sputter gases and mixture ratios for processes that use multiple sputter gases.

Apparatus has been in use for some time for depositing sputtered atoms on a substrate to produce a layer of material defined by the sputtered atoms. The technique of sputtering material from a target to deposit on a substrate is commonly referred to as physical vapor deposition (PVD).

Typical sputtering systems produce such a deposition by producing a plasma discharge between an anode and a target, which acts as a cathode, to obtain an emission of sputtered atoms from the target. An electric field in the vicinity of the target causes ions to bombard the surface of the sputter target. Electric fields can be applied using an alternating current (ac) power supply or a dc power supply. When, for example, an aluminum sputter target is bombarded with the ions of an inert gas such as argon, upon the application of the applied electric field, the target emits sputtered atoms of aluminum. The sputtered atoms travel to the substrate and become deposited on the substrate to produce a layer of the sputtered material. In systems in which an inert gas, or combination of inert gases, the method is commonly referred to as non-reactive physical vapor deposition. In non-reactive physical vapor deposition, the deposited layer is typically of the same stoichiometric composition as the target material. In this simplest case, which is typically used to produce films of a single element, such as a metal, and in which the target material is conductive, the plasma can be generated with a direct current (dc) applied to the target.

In most, if not all, sputtering equipment, a magnetic field is introduced in the vicinity of the sputter target to enhance the movement of electrons and subsequent ionization of the neutral gas and enable operation of the apparatus in the optimal sputter pressure regimes between 0.001 to 0.01 Torr within which sputtering yields from the target are optimal. Sputtering tools that utilize magnetic fields are typically referred to as magnetrons.

Variations on the ac powering scheme can also be implemented as a means to provide additional levels of process control not available in the simplest dc powered case. A split cathode system, for example can be used to independently control the uniformity of the thin film deposition by providing a means for independently controlling the removal rate of sputtered material from a plurality of targets. Multiple radio frequency powers can also be applied to control the properties of the deposited thin films.

An alternative to the non-reactive sputtering or non-reactive physical vapor deposition is reactive sputtering or reactive physical vapor deposition. In reactive sputtering, the deposited film is formed by plasma activated chemical reaction between a target material (metal, semiconductor, alloy) and a reactive gas such as oxygen or nitrogen which is mixed with an inert gas such as argon and introduced into a vacuum chamber equipped with a plasma source such as a magnetron.

Reactive sputtering methods are widely used in numerous electronic and surface engineering applications to produce thin dielectric films having certain functional characteristics. Silicon dioxide, for example, can be deposited using the reactive sputtering technique by introducing a mixture of argon and oxygen to a sputtering system equipped with a silicon sputter target. The oxygen in the mixture reacts with the sputtered silicon to form silicon dioxide. Similar reactions can occur using aluminum to form aluminum oxide, for example, or other materials which can react with oxygen to create a deposited film that incorporates oxygen with another element or combination of elements from the sputter target. The sputter target need not be made of a single element.

Alternatively, nitrogen can be mixed with an inert gas such as argon and introduced into the sputtering system to produce a reaction between the nitrogen and the sputtered target material to create a deposited film that that incorporates nitrogen with another element or combination of elements from the sputter target. When aluminum is sputtered in the presence of nitrogen, for example, a deposited aluminum nitride layer can be formed on the substrate.

Two main approaches to power delivery for reactive sputtering are commonly employed: 1) pulsed dc, which is usually applicable for single target magnetron powering and 2) mid-frequency or alternating current (ac) powering, which is most effective for dual or other split cathode magnetron arrangements. Typical ac frequencies used in ac powered, split cathode configurations are in the range of 20-200 kHz.

The origin and evolution of intrinsic stress in thin films or structures of thin films can be viewed, for example, in terms of the processes responsible for the formation of the film microstructure. The type of stress, either compressive or tensile, and the magnitude of the stress have been shown to vary with the magnitude of the flux and energy of particles impinging on the growing film as reported by Windischmann, for example. The majority of magnetron sputtered metal films have a relatively low-density structure corresponding to zones 1 or T of the Structure Zone Model, as reported by Thornton, in which microvoids lead to the generation of tensile stress. Compressive stress is generated by an “atomic peening” mechanism whereby ions or accelerated neutrals from the plasma bombard the growing film creating interstitial atoms in the deposited film. Reactively sputtered oxide and nitride films often exhibit a tendency toward compressive stress due to a high concentration of reactive (for example, nitrogen or oxygen) gas atoms entrapped into the interstitial positions in the crystal lattice of the growing films.

The most effective methods for reducing the tensile stress in growing films employ ion assisted deposition and sputtering with substrate bias which enhance the ion bombardment of the film during deposition as reported by Chiu, et al. Ion bombardment during deposition results in argon entrapment and atomic peening, which promotes the displacement of surface atoms towards deeper positions in the bulk of the growing films leading to the filling of voids and atomic level vacancies and the formation of crystalline defects such as interstitial atoms.

In contrast, compressive stress can be reduced by restricting the generation of interstitial atoms by reducing the flux, by reducing the energy, or by reducing both the flux and the energy of energetic species arriving from the magnetron plasma discharge to the surface of the growing film. Compressive stress in the growing films can also be reduced by depositing the films at elevated temperature (higher adatom mobility allows interstitial atoms to be incorporated in the lattice) and by increasing the pressure of the sputter gas during the deposition of the films (sputtered atoms and ions experience more collisions with Ar atoms thus losing their energy before reaching the substrate).

In general, published results from investigations of stress in aluminum nitride films are consistent with known models. Este and Westwood reported that intrinsic stress in the films deposited from a planar aluminum target using an rf discharge in argon/nitrogen mixtures changed drastically with increasing gas pressure from compressive −19 GPa to tensile +2.5 GPa. (In this context, a negative or minus stress is compressive and a positive or plus stress is tensile.) It was suggested that high compressive stress is due to bombardment of the film by energetic neutral nitrogen atoms reflected from the target, which is reduced as pressure is increased. Iriarte et al. completed a systematic study of the influence of the main process parameters on residual stress in fully textured polycrystalline aluminum nitride films deposited by a reactive pulsed dc magnetron. They revealed the effects of sputter gas pressure on stress through atom-assisted and atomic peening mechanisms. Dubois and Muralt showed that residual stress in aluminum nitride films deposited on a Pt electrode by reactive pulsed dc magnetron depended essentially on ion bombardment and on the sputtering pressure. Martin at al. found that aluminum nitride films deposited on Mo and Pt electrodes using pulsed dc sputter technology had inherent tensile stress, which might be reduced by depositing the aluminum nitride with a negative substrate bias.

There is sparse information in the literature related to the stress behavior of ac reactively sputtered highly oriented aluminum nitride films. It was reported by Oshmyansky et al. that residual stress in the aluminum nitride films reactively deposited utilizing an ac powered magnetron with a dual-ring target configuration might be controlled partly by manipulating gas pressure and partly by manipulating magnetic field. Stress was changed from tensile +300 MPa to highly compressive −1.3 GPa when the magnetic field strength was increased from 220 to 600 gauss. It is necessary to point out that implementing aluminum nitride film stress control by manipulating the magnetic field influences the erosion profile of the sputtering target and, also, that it is a technically inconvenient method for industrial sputtering equipment. Adjustment of the pressure is also inconvenient since pressure can greatly affect other important characteristics of the sputter deposited films.

In the optimization of a sputter deposition process, a number of parameters are typically optimized and controlled to determine the final set of hardware and conditions to be used to produce the films, and ultimately the structures of films that are used to fabricate a device. Typical parameters include the process pressure, the frequency of the applied power to the target or targets and to the substrate in cases where substrate bias is applied, the applied power level or levels to the target or targets if a split cathode is used, the gas flow or flows if a mixture is used, and the substrate temperature, among others.

It is well known that aluminum nitride films with preferred specific crystallographic orientation exhibit the highest levels of piezoelectric properties. These films have columnar grain structure with preferred crystal orientation (002) perpendicular to the substrate surface. Quantitatively, film crystal orientation is characterized by full width at half maximum (FWHM) of x-ray rocking curve measurements. Reactive sputtering is well-suited for the production of highly oriented aluminum nitride, for example, with FWHM of<2 degree on lightly doped silicon wafers. Deposition on metal underlayers, however, is often challenging because the crystal orientation of the deposited aluminum nitride films depends on the crystallographic orientation of the underlayers, on the surface roughness, surface cleanliness, among other properties of the bottom electrode upon which the aluminum nitride is deposited.

In addition to controlling the crystallographic orientation and grain structure of the bottom metal electrode and the aluminum nitride, control of the intrinsic stress is an important factor in the fabrication of the thin film structures employed in electro-acoustic devices, and in particular in devices in which the aluminum nitride film is sandwiched between two metal electrodes, such as, molybdenum electrodes.

Technological solutions that enable the formation of highly oriented and low-stress aluminum nitride piezoelectric films and molybdenum electrodes are, therefore, of high interest to the piezoelectric resonator community.

Reactive sputtering is typically employed to produce high quality aluminum nitride and other piezoelectric insulating films while conventional dc magnetron is more commonly used for depositing metal electrodes such as Pt, Ti, Al, Ru, Cr, Ir, Os, Ag, Au, W, and Mo, among others.

It is the object of the present invention to provide a sputtering method that enables control of both the crystallographic orientation and the stress of sputter deposited films of these and other materials.

### SUMMARY

Effective stress control is disclosed in the present invention in the fabrication of aluminum nitride-based, piezoelectric film structure with molybdenum top and bottom electrodes, for example, in a dual cathode sputtering tool such as the S-Gun provided by Tegal Corporation.

In a preferred embodiment, a seed layer is deposited onto a substrate to promote a preferred crystal orientation for the bottom electrode layer. The preferred crystal orientation in the seed layer need not be the same as that in the film that is to be deposited onto the seed layer. In general, the seed layer promotes formation of a preferred crystalline orientation in the layer deposited above the seed layer. In this context, the term bottom electrode is intended to signify the lower of the two electrodes between which an insulating film is deposited. In the preferred embodiment, the seed layer is deposited within the same cluster tool in a separate process module that is used to deposit either the electrodes or the piezoelectric layer. In other embodiments, the seed layer is deposited on a different sputtering tool than the one used to deposit the electrode and piezoelectric insulating layer or using a non-sputtering technique. In a preferred embodiment in which the bottom electrode material is molybdenum, and in which the piezoelectric film is aluminum nitride with a preferred crystal orientation of (002), titanium or aluminum nitride is used as the seed layer.

After the seed layer has been deposited, a two-step sputter process is used to deposit the bottom electrode. The first step of the two-step deposition process is used to deposit a first part of the bottom electrode layer to promote a preferred crystal orientation in the growing bottom electrode film. This first part of the bottom electrode layer is deposited without substrate bias (or with low substrate bias, preferably less than 10 W) to produce a favorable crystalline orientation in the growing film.

A second step of the two-step sputter deposition process is then used to deposit a second part of the bottom electrode layer with process conditions that are used to control the film stress in the deposited film. This second part of the bottom electrode layer can be deposited, for example, at relatively low substrate bias to have tensile or near-zero stress in the film. Substrate biases in the second step are typically less than 100 W. Alternatively, the second part of the bottom electrode layer can be deposited at relatively high substrate bias to achieve high compressive stress in the second part of the bottom electrode layer, if required.

Piezoelectric insulating films are typically deposited with alternating current reactive sputtering equipment. In the preferred embodiment described in this invention, a two step process is described that also consists of a first step in which no or low substrate bias is used to allow the crystalline orientation for a first part of the growing film to be affected primarily by the surface condition of the substrate or the seed layer, and a second step in which substrate bias is applied during sputter deposition to control stress in the growing film. The substrate bias in the second step is typically greater than 0 watts and less than 100 watts.

A method for controlling crystalline orientation and stress in metal electrodes and insulating films used in metal-insulator-metal film structures is described. Specifically, a method for controlling crystalline orientation and stress in metal electrodes and insulating films is described for structures and materials that are commonly used in the fabrication of devices that utilize piezoelectric materials such as aluminum nitride.

Stress in the aluminum nitride and molybdenum films, for example, is effectively controlled by performing a two step process with a first step in which little or no substrate bias is used to promote desired crystalline orientation, and a second step in which a substrate bias is applied during the sputter deposition step to promote stress control.

### BRIEF DESCRIPTION OF THE DRAWINGS

FIG. 1 shows a schematic of the S-Gun magnetron manufactured by Tegal Corporation;

FIG. 2 shows the crystal orientation (FWHM) of 1300 nm thick aluminum nitride films for a range of crystal orientations (FWHM) in underlying 300 nm thick molybdenum films;

FIG. 3 shows the crystal orientation (FWHM) and intrinsic stress in 300 nm thick molybdenum films deposited by dc powered S-Gun with substrate rf bias;

FIG. 4 shows the process flow for the inventive process to produce a multilayer deposition;

FIG. 5a shows a scanning electron microscope image for a 300 nm thick molybdenum film deposited on a thermally oxidized silicon wafer by inventive two-step process (with 15 nm thick aluminum nitride seed layer);

FIG. 5b shows an atomic force micrograph of the same 300 nm thick molybdenum film deposited on thermally oxidized silicon wafer by inventive two-step process (with 15 nm thick aluminum nitride seed layer) as shown in the SEM in FIG. 4a;

FIG. 6 shows cross-sectional SEM image of a well oriented aluminum nitride film (FWHM=1.3°) on a molybdenum electrode (FWHM=2°) deposited onto thermal oxidized Si wafer with aluminum nitride seed layer using the inventive process;

FIG. 7 shows the x-ray rocking curves of 1300 nm thick aluminum nitride film on 300 nm thick molybdenum electrode; and

FIG. 8 shows stress in 1000 nm thick aluminum nitride films plotted for a range of substrate rf bias powers.

### DETAILED DESCRIPTION OF THE PREFERRED EMBODIMENTS

In one embodiment of the present invention, preferred crystal orientation and effective stress control are achieved simultaneously in piezoelectric aluminum nitride films deposited with ac (for example, 40 kHz) reactive sputtering processes using a dual cathode S-Gun magnetron, and also in molybdenum electrodes deposited by a dc powered version of the S-Gun. In this preferred embodiment, the sputter system employed is the Endeavor-AT manufactured by Tegal Corporation equipped with the S-Gun magnetrons, but the result of this invention can be applied to other deposited films and other sputter systems.

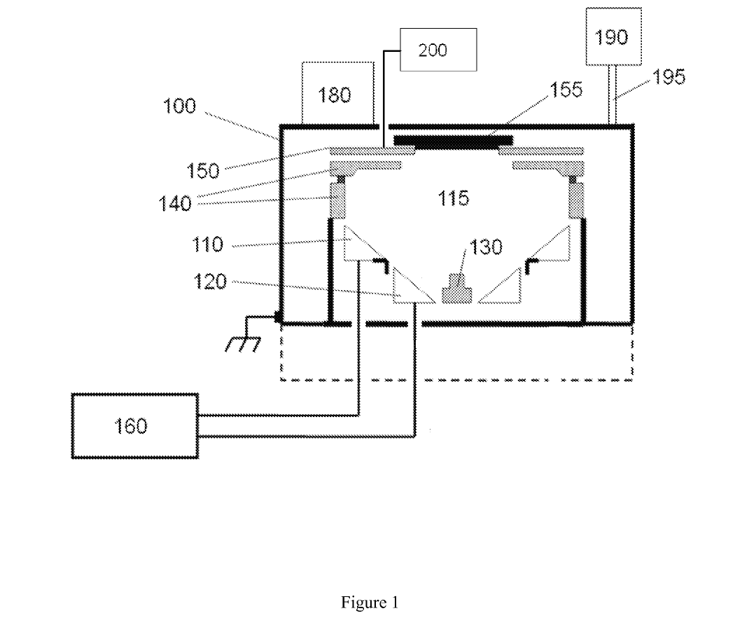

In the schematic illustration provided in FIG. 1, a number of key attributes of the preferred embodiment are shown. The preferred embodiment consists of a process chamber 110 within which is contained a cavity 115. Two conical sputter targets, an outer sputter target 110 and an inner sputter target 120, are mounted concentrically around a center shield 130. Center shield 130 can receive a bias, can be left floating, or can be grounded. Additional shields 140 in the preferred embodiment are shown at the top and periphery of the process chamber 110. A wafer land 150 is shown supporting substrate 155 at the top of the process chamber in this preferred embodiment in which the side of the substrate upon which the sputtered layer is deposited faces downward into the cavity 115 containing sputter targets 110 and 120. Wafer land 150 is connected to a power supply 200 to produce a bias on the wafer during deposition when required.

In the preferred embodiment for reactive sputtering of aluminum nitride and other dielectric films, an ac power supply 160 with a bimodal output signal is electrically connected between the outer sputter target 110 and the inner sputter target 120. In another preferred embodiment for the sputtering of metal films, power supply 160 is a dc power supply.

Additionally, the process chamber has an attached vacuum pumping system 180 that typically consists of a turbomolecular pump and a backing pump such as a diaphragm pump. A gas source 190 is connected through a gas delivery system to provide the process gases required for operation of the sputter system. Typical operating pressures for the sputter system in the preferred configuration are between 0.001 Torr and 0.010 Torr.

In operation during in this preferred embodiment, the sputtering tool is evacuated to a base pressure of less than the operating pressure, and preferably less than 1×10⁻⁷Torr using vacuum pumping system 180. In the case in which the preferred embodiment is used to reactively sputter deposit a film, argon gas mixed with a reactive gas such as oxygen or nitrogen, is provided from gas source 190 and delivered to process chamber 110 through gas delivery system 195. A plasma discharge is generated by applying power from power supply 160 at between 20-200 kHz, and preferably 40 kHz, between the sputter targets 110 and 120. Magnetic fields are generally present in the vicinity of sputter targets 110 and 120 to enhance ionization of the process gas. Typical aluminum nitride ac reactive sputtering processes achieve deposition rates of approximately 60 nm/min at a cathode power of 5.5 kW.

In another preferred embodiment in which a reactive sputtering process is not required as, for example, for the deposition of metal films, argon gas is provided from gas source 190 and delivered to process chamber 110 through gas delivery system 195. A plasma discharge is generated by applying dc power from power supply 160. Magnetic fields are present in the vicinity of the sputter targets 110 and 120 to enhance ionization of the process gas. Typical dc sputtering processes for molybdenum have deposition rates of 400 nm/min at a cathode power of 6 kW.

In the S-Gun configuration manufactured by Tegal Corporation, the material from the sputter targets 110 and 120 travels upward toward a substrate and lands on the side of the substrate 155 that faces downward toward the sputter targets. The substrate 155 facing the sputter targets 110 and 120 can be either the frontside or the backside of the wafer depending on which side of the wafer requires the sputter deposited film. The wafer support assembly 150 is connected to power supply 200.

In the embodiment in which the wafer assembly 150 provides for biasing of the substrate, rf power is applied to the wafer support assembly 150 from power supply 200, typically, in the range of 0-100 watts, igniting a rf plasma discharge in the wafer vicinity, which generates a negative self-bias potential on the substrate 155 resulting in ion bombardment during film growth.

In the preferred embodiment, aluminum nitride and molybdenum films are deposited at ambient temperature, without external heating, although the S-Gun is equipped with a heater that could be utilized.

For pre-deposition wafer treatment, a capacitively coupled planar rf plasma etch module is typically employed to pre-clean the wafer surface prior to deposition.

In-plane residual stress (stress parallel to the substrate surface) in the deposited films was calculated using maps of the wafer curvature radius before and after deposition obtained by an FSM-128, laser beam-based thin film stress and flatness measurement system. A Philips X'Pert MRD X-ray diffractometer was employed to measure the crystallographic orientation of deposited films. A plot of the full width at half maximum (FWHM) values for sputter-deposited aluminum nitride films (002) and molybdenum (110) diffraction peaks were measured by completing rocking curve measurements in three points on each sample. Scanning electron microscope (SEM) and atomic force microscope (AFM) observations were used also to explore the film morphology and grain structure.

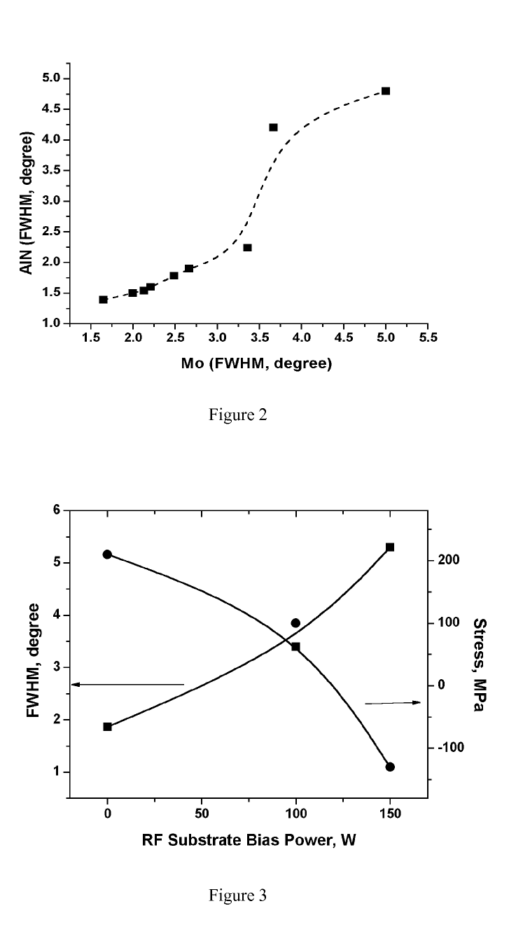

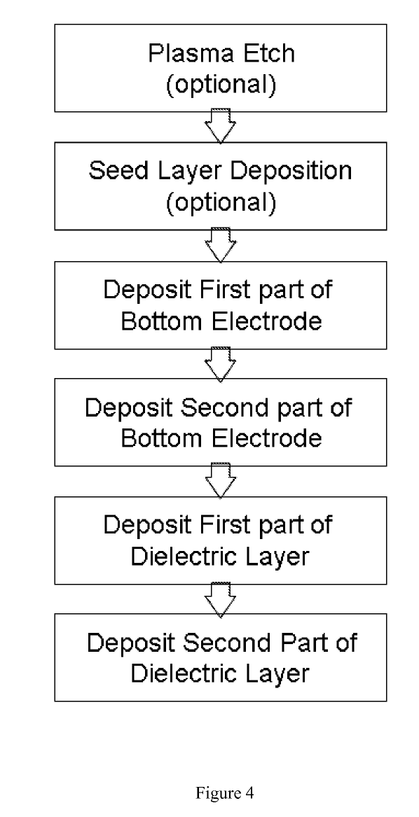

FIG. 2 shows that the full width at half maximum value (FWHM) for aluminum nitride films directly correlates with the FWHM value of the molybdenum underlayer. Highly oriented aluminum nitride films with FWHM <2° have been obtained on molybdenum electrodes when FWHM crystallographic orientation of the underlying molybdenum is less than 3°.

FIG. 3 shows that as rf bias on the wafer support assembly 150 is increased, stress levels in deposited molybdenum films are reduced and that the least acceptable crystal orientations are produced in the molybdenum films where the diffraction angle is >2 degrees. It is the intent of the present invention to overcome the limitation imposed on achieving both desirable crystallographic orientation and low stress.

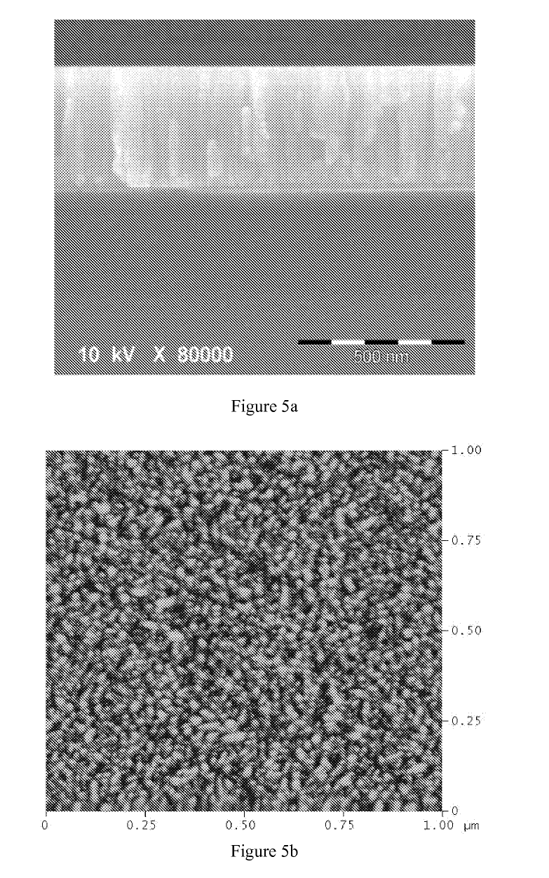

In the present invention, a two-step molybdenum deposition process is taught that provides a method for creating superior crystal orientation in sputtered films in combination with near zero or, if required, compressive stress in deposited molybdenum films. The process flow for the bottom molybdenum electrode consists of a rf plasma etch of the wafer and a “seed layer” deposition to initiate oriented molybdenum grain growth at the start of the sputter deposition process. Thin titanium or aluminum nitride films can be used as seed layers to initiate preferred molybdenum grain growth. Deposition of the first 10-30% of the total thickness of the molybdenum electrode is completed in the preferred embodiment without rf bias on substrate 155. The remaining 70-90% of the molybdenum film is deposited with bias. The molybdenum electrodes deposited by this technique exhibit strong (110) crystallographic orientation with FWHM <2° and have a columnar grain structure and pebble-like surface morphology with root mean square surface roughness of approximately 0.5 nm as shown in FIGS. 5a and 5b.

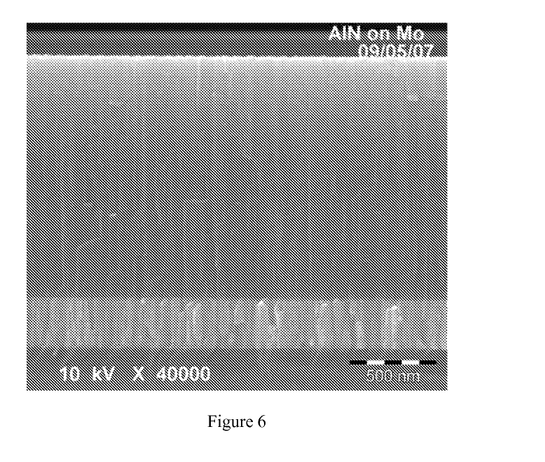

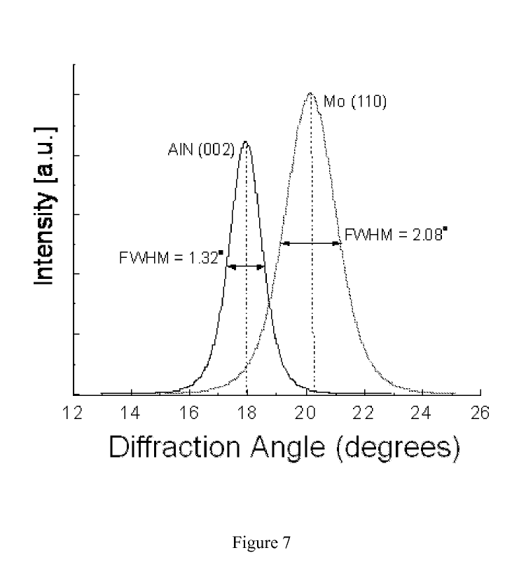

The formation of bottom electrodes with preferred crystallographic orientation enables the growth of highly oriented aluminum nitride films with very sharp (002) X-ray diffraction peaks (FWHM=1.3° and 0.9° for 1000 nm and 2000 nm thick films, respectively). FIG. 6 shows a cross-sectional SEM image of well oriented aluminum nitride film that was deposited on a molybdenum electrode. Additionally, FIG. 7 shows x-ray rocking curves of the same aluminum nitride and molybdenum films that also demonstrate the preferred crystallographic orientations of FWHM=1.3° for aluminum nitride and a FWHM=2° for the molybdenum films that are available using the inventive process.

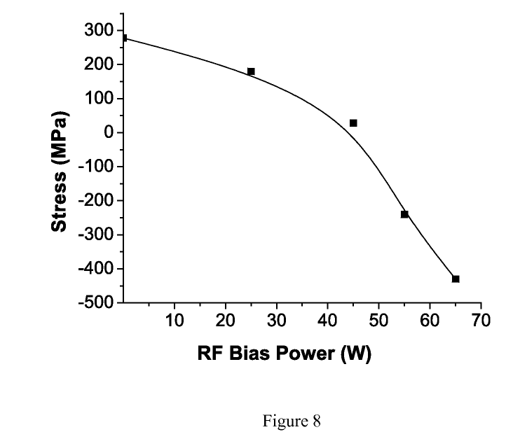

In general, the optimization of the aluminum nitride reactive sputtering process by the S-Gun is performed to optimize the crystallographic orientation of the film to produce, in the ideal case, as close to a perfect (002) crystal orientation, with optimized film thickness and uniformity prior to introducing the stress adjustment. If the preliminary optimized deposition process produces tensile stress, the S-Gun, by design, creates the opportunity for reducing the stress value to zero, or converting it to compressive stress, by means of film deposition with active rf substrate bias using power supply 200. Applying relatively low rf power in the range of 0-60 W enables a remarkable stress tailoring in the films from tensile +300 MPa to compressive −500 MP as illustrated in FIG. 8.

The two-step deposition process taught in the present invention overcomes the limitations of current sputtering tools and processes for obtaining preferred crystal orientation in molybdenum films deposited with rf bias compared to the films deposited without rf bias. The two-step deposition for controlling the preferred crystallographic orientation in deposited molybdenum films behaves similarly for aluminum nitride. That is, the two-step process eliminates the observed limitations of existing tools and processes for achieving preferred crystallographic orientation of deposited films when aluminum nitride thin films are deposited with substrate bias. In the first step of the two-step process, the deposition is performed without bias on substrate 155 during film nucleation and initial grain formation, and then in the second step of the two-step process, rf bias is applied to substrate 155 during bulk film growth to preserve the preferred crystallographic orientation and to reduce tensile stress in the deposited aluminum nitride films. In this preferred embodiment, the deposition of aluminum nitride films on underlying molybdenum films with preferred crystallographic orientation is taught. This approach, however, is not limited to the use of aluminum nitride as the dielectric or to molybdenum as the underlying metal layer upon which the crystallographically-oriented dielectric layer is deposited. The two-step approach taught in the present invention can be effective for depositing any dielectric or conductive thin films that is reactively sputtered and any metal film that is sputtered using dc power applied to the target or targets. Examples of other films that can be deposited using the present invention are titanium nitride, silicon nitride, aluminum oxide, silicon oxide, chromium oxynitride, tantalum oxide, tantalum nitride, platinum, chromium, nickel, nickel vanadium, ruthenium, iridium, among many others in which the sputter deposited films require preferred crystallographic orientation and low stress levels.

Other embodiments of the sputtering equipment and the applicable film structures will be apparent to persons of ordinary skill in the art. The invention is, therefore, to be limited only as indicated by the scope of the appended claims.

### REFERENCES

H. Windischmann, J. Vac. Sci. Technol. A9, 2431 (1991).

J. A. Thornton, J. Vac. Sci. Technol. A4, 3059 (1986).

H. Windischmann, Crit. Rev. Solid State Mater. Sci. 17, 547 (1992).

K. F. Chiu, Z. H. Barber, and R. E. Somekh, Thin Solid Films, 39-42, 343 (1999).

G. Este and W. D. Westwood, J. Vac. Sci. Technol. A5, 1892 (1987).

G. Iriarte, F. Engelmark, M. Ottosson, and I. Katardjiev, J. Mater. Res. 18, 423 (2003).

Y. Oshmyansky, J. Larson, R. Ruby, and S. Mishin, Semicond. Int., March 2003.

What is claimed is:

1. A method to achieve a film having a desired crystal texture and a desired stress level, the method comprising:
forming a first portion of the film, the first portion optimized for achieving the desired crystal texture; and
forming a second portion of the film on the first portion of the film, the second portion optimized for achieving the desired stress level.

2. A method as in claim 1 wherein forming the second portion of the film without first forming the first portion does not achieve the desired crystal texture.

3. A method as in claim 1 further comprising
forming a second film having both desired crystal texture and desired stress level on the film.

4. A method as in claim 1 further comprising
forming a first portion of a second film on the second portion of the film, the first portion optimized for achieving the desired crystal texture; and
forming a second portion of the second film on the first portion of the second film, the second portion optimized for achieving the desired stress level.

5. A method as in claim 1 wherein the first and second portions of the second layer are abruptly transitioned.

6. A method as in claim 1 wherein the first and second portions of the second layer are gradually transitioned.

7. A method as in claim 1 further comprising
forming a seed layer enabling promotion of the desired crystal texture before forming the first portion of the film.

8. A method to achieve an electrode having a desired crystal orientation and a desired stress level, the method comprising:
sputtering a first portion of the electrode with a first bias power, the first bias power optimized for achieving the desired crystal orientation; and
sputtering a second portion of the electrode on the first portion with a second bias power, the second bias power optimized for achieving the desired stress level.

9. A method as in claim 8 wherein the first and second portions of the electrode are abruptly transitioned.

10. A method as in claim 8 wherein the first and second portions of the electrode are gradually transitioned.

11. A method as in claim 8 wherein the first bias power is less than 10 W.

12. A method as in claim 8 wherein the second bias power is greater than 0 W.

13. A method as in claim 8 wherein the crystal orientation comprises one of (110) orientation for Mo and (111) for Al.

14. A method as in claim 8 wherein the electrode comprises one of Mo, Pt, Ti, Al, Ru, Cr, Ir, Os, Ag, Au, and W.

15. A method as in claim 8 wherein the first portion comprises between 10 to 30% of the electrode.

16. A method as in claim 8 wherein the second portion comprises between 70 to 90% of the electrode.

17. A method as in claim 8 further comprising
forming a seed layer enabling promotion of the desired crystal texture before forming the first portion of the electrode.

18. A method as in claim 17 wherein the seed layer comprises one of Ti and AlN.

19. A method as in claim 17 wherein the thickness of the seed layer is between 10 to 30 nm.

20. A method as in claim 8 further comprising
sputtering a second film having both desired crystal texture and desired stress level on the electrode.

21. A method to achieve a piezoelectric film having a desired crystal orientation and a desired stress level, the method comprising:
sputtering a first portion of the piezoelectric film with a first bias power, the first bias power optimized for achieving the desired crystal orientation; and
sputtering a second portion of the piezoelectric film on the first portion with a second bias power, the second bias power optimized for achieving the desired stress level.

22. A method as in claim 21 wherein the first and second portions of the piezoelectric film are abruptly transitioned.

23. A method as in claim 21 wherein the first and second portions of the piezoelectric film are gradually transitioned.

24. A method as in claim 21 wherein the first bias power is less than 10 W.

25. A method as in claim 21 wherein the second bias power is greater than 0 W.

26. A method as in claim 21 wherein the piezoelectric film comprises AlN.

27. A method as in claim 26 wherein the crystal orientation comprises (002) orientation.

28. A method as in claim 21 wherein the first portion comprises between 10 to 30% of the piezoelectric film.

29. A method as in claim 21 wherein the second portion comprises between 70 to 90% of the piezoelectric film.

30. A method as in claim 21 further comprising
sputtering an electrode with the desired crystal texture before sputtering the first portion of the piezoelectric film.

31. A method to achieve a structure having a desired crystal orientation and a desired stress level, the method comprising:
sputtering a first portion of an electrode with a first bias power, the first bias power optimized for achieving the desired crystal orientation;
sputtering a second portion of the electrode on the first portion with a second bias power, the second bias power optimized for achieving the desired stress level;
sputtering a first portion of the piezoelectric film on the electrode with a third bias power, the third bias power optimized for achieving the desired crystal orientation; and
sputtering a second portion of the piezoelectric film on the first portion with a fourth bias power, the fourth bias power optimized for achieving the desired stress level.

32. A method as in claim 31 wherein the first and third bias power is less than 10 W.

33. A method as in claim 31 wherein the second and fourth bias power is greater than 0 W.

34. A method as in claim 31 wherein the electrode comprises one of Mo, Pt, Ti, Al, Ru, Cr, Ir, Os, Ag, Au, and W.

35. A method as in claim 31 wherein the first portion comprises between 10 to 30% of the electrode and the piezoelectric film.

36. A method as in claim 31 wherein the second portion comprises between 70 to 90% of the electrode and the piezoelectric film.

37. A method as in claim 31 further comprising
sputtering a seed layer enabling promotion of the desired crystal texture before sputtering the first portion of the electrode.
